(19) United States
(12) Patent Application Publication
(10) Pub. No.: US 2024/0114712 A1
(43) Pub. Date: Apr. 4, 2024

(54) DISPLAY APPARATUS

(71) Applicant: Samsung Display Co., Ltd., Yongin-si (KR)

(72) Inventors: Sangmin Hong, Yongin-si (KR); Heeseong Jeong, Yongin-si (KR); Seunghan Kim, Yongin-si (KR); Nari Heo, Yongin-si (KR)

(73) Assignee: Samsung Display Co., Ltd., Yongin-si (KR)

(21) Appl. No.: 18/354,126

(22) Filed: Jul. 18, 2023

(30) Foreign Application Priority Data
Oct. 4, 2022 (KR) 10-2022-0126583

(51) Int. Cl. H10K 50/19; H10K 59/40; H10K 59/80; H10K 59/12

(52) U.S. Cl. CPC H10K 50/19; H10K 59/40; H10K 59/873; H10K 59/879; H10K 59/12

(57) ABSTRACT

A display apparatus includes a display element including a first emission layer disposed on a substrate and a second emission layer disposed on the first emission layer, a first capping layer disposed on the display element, a second capping layer disposed on the first capping layer, a thin-film encapsulation layer including a lower inorganic encapsulation layer in contact with the second capping layer, and a light-blocking layer disposed on the thin-film encapsulation layer and including an opening corresponding to an emission area of the display element. The lower inorganic encapsulation layer has a refractive index greater than a refractive index of the second capping layer.

### CROSS-REFERENCE TO RELATED APPLICATION

This application claims priority to and benefits of Korean Patent Application No. 10-2022-0126583 under 35 U.S.C. § 119, filed in the Korean Intellectual Property Office (KIPO) on Oct. 4, 2022, the entire contents of which are incorporated herein by reference.

### BACKGROUND

### 1. Technical Field

One or more embodiments relate to a display apparatus capable of increasing light efficiency and preventing recognition of a color shift according to a viewing angle.

### 2. Description of the Related Art

Recently, applications of display apparatuses have diversified. In addition, since display apparatuses are thin and lightweight, the range of use of display apparatuses is widening, and research on display apparatuses that can be used in various fields is being continuously conducted.

It is to be understood that this background of the technology section is, in part, intended to provide useful background for understanding the technology. However, this background of the technology section may also include ideas, concepts, or recognitions that were not part of what was appreciated by those skilled in the pertinent art prior to a corresponding effective filing date of the subject matter disclosed herein.

### SUMMARY

Display elements provided in a display apparatus emit light of a color and provide an image. The emitted light may pass through a sealing member for sealing the display elements. When the sealing member has a stacked structure of multiple layers, a color of light emitted from a display element may be shifted.

Embodiments provide a display apparatus capable of increasing light efficiency and preventing recognition of a color shift according to a viewing angle. However, the embodiments of the disclosure are not limited to those set forth herein.

Additional aspects will be set forth in part in the description which follows and, in part, will be apparent from the description, or may be learned by practice of the presented embodiments of the disclosure.

According to one or more embodiments, a display apparatus includes a display element including a first emission layer disposed on a substrate and a second emission layer disposed on the first emission layer, a first capping layer disposed on the display element, a second capping layer disposed on the first capping layer, a thin-film encapsulation layer including a lower inorganic encapsulation layer in contact with the second capping layer, and a light-blocking layer disposed on the thin-film encapsulation layer and including an opening corresponding to an emission area of the display element. The lower inorganic encapsulation layer may have a refractive index greater than a refractive index of the second capping layer.

In an embodiment, the refractive index of the lower inorganic encapsulation layer may be in a range of about 1.59 to about 1.95.

In an embodiment, the lower inorganic encapsulation layer may include a first inorganic encapsulation layer in contact with the second capping layer and a second inorganic encapsulation layer disposed on the first inorganic encapsulation layer, and the first inorganic encapsulation layer may have a refractive index greater than a refractive index of the second inorganic encapsulation layer.

In an embodiment, the refractive index of the first inorganic encapsulation layer may be in a range of about 1.46 to about 1.95.

In an embodiment, a thickness of the first inorganic encapsulation layer may be less than a thickness of the second inorganic encapsulation layer.

In an embodiment, the first capping layer may have a refractive index greater than the refractive index of the second capping layer.

In an embodiment, the refractive index of the first capping layer may be in a range of about 1.8 to about 2.4, and the refractive index of the second capping layer may be in a range of about 1.2 to about 1.8.

In an embodiment, the display element may further include a pixel electrode disposed under the first emission layer and an opposite electrode disposed on the second emission layer.

In an embodiment, the thin-film encapsulation layer may include an upper inorganic encapsulation layer disposed on the lower inorganic encapsulation layer and an organic encapsulation layer arranged between the lower inorganic encapsulation layer and the upper inorganic encapsulation layer.

In an embodiment, the display apparatus may further include a color filter filling the opening of the light-blocking layer.

According to one or more embodiments, a display apparatus includes a pixel electrode disposed on a substrate, a plurality of emission layers disposed on the pixel electrode and overlapping each other in a plan view, an opposite electrode disposed on the plurality of emission layers, a first capping layer disposed on the opposite electrode, a second capping layer disposed on the first capping layer, a first inorganic encapsulation layer in contact with the second capping layer, and a light-blocking layer disposed on the first inorganic encapsulation layer and including at least one opening corresponding to the plurality of emission layers. Each of a refractive index of the first capping layer and a refractive index of the first inorganic encapsulation layer may be greater than a refractive index of the second capping layer.

In an embodiment, the refractive index of the first inorganic encapsulation layer may be in a range of about 1.59 to about 1.95.

In an embodiment, the display apparatus may further include a second inorganic encapsulation layer disposed on the first inorganic encapsulation layer, and the refractive index of the first inorganic encapsulation layer may be greater than a refractive index of the second inorganic encapsulation layer.

In an embodiment, the refractive index of the first inorganic encapsulation layer may be in a range of about 1.46 to about 1.95, and the refractive index of the second inorganic encapsulation layer may be in a range of about 1.41 to about 1.78.

In an embodiment, a thickness of the first inorganic encapsulation layer may be less than a thickness of the second inorganic encapsulation layer.

In an embodiment, a thickness of the first inorganic encapsulation layer may be greater than a thickness of each of the first capping layer and the second capping layer.

In an embodiment, the refractive index of the first capping layer may be greater than the refractive index of the second capping layer.

In an embodiment, the display apparatus may further include an organic encapsulation layer disposed on the first inorganic encapsulation layer and an upper inorganic encapsulation layer disposed on the organic encapsulation layer.

In an embodiment, the display apparatus may further include a touch sensing layer arranged between the upper inorganic encapsulation layer and the light-blocking layer.

In an embodiment, the display apparatus may further include a color filter filling the at least one opening of the light-blocking layer.

### BRIEF DESCRIPTION OF THE DRAWINGS

An additional appreciation according to the embodiments of the disclosure will become more apparent by describing in detail the embodiments thereof with reference to the accompanying drawings, wherein:

FIG. 1 is a schematic plan view of a portion of a display apparatus according to an embodiment;

FIG. 2 is a schematic diagram of an equivalent circuit of a pixel included in the display apparatus of FIG. 1;

FIG. 3 is a schematic cross-sectional view of a display apparatus according to an embodiment, and is a schematic cross-sectional view of the display apparatus taken along line I-I′ of FIG. 1;

FIG. 4 is an enlarged schematic cross-sectional view of portion II of FIG. 3, according to an embodiment;

FIG. 5 is an enlarged schematic cross-sectional view of portion II of FIG. 3, according to another embodiment;

FIG. 6 is a graph schematically showing a color shift of a display apparatus via a color system ‘CIE 1931’, according to an embodiment; and

FIG. 7 is a schematic cross-sectional view of a display apparatus according to an embodiment.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

Unless otherwise specified, the illustrated embodiments are to be understood as providing features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the disclosure. Also, like reference numerals denote like elements.

Although the terms “first,” “second,” etc. may be used herein to describe various elements, these elements should not be limited by these terms. These terms are used to distinguish one element from another element. Thus, a first element discussed below could be termed a second element without departing from the teachings of the disclosure.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising, “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

In the following embodiment, it will be understood that when a layer, region, or component is referred to as being “formed on” another layer, region, or component, it can be directly or indirectly formed on the other layer, region, or component. That is, for example, intervening layers, regions, or components may be present.

In the following embodiment, the x-axis, the y-axis, and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

In the specification, the expression “A and/or B” may be understood to mean “A, B, or A and B”.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the disclosure. Further, the blocks, units, and/or modules of some embodiments may be physically combined into more complex blocks, units, and/or modules without departing from the scope of the disclosure.

The terms “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

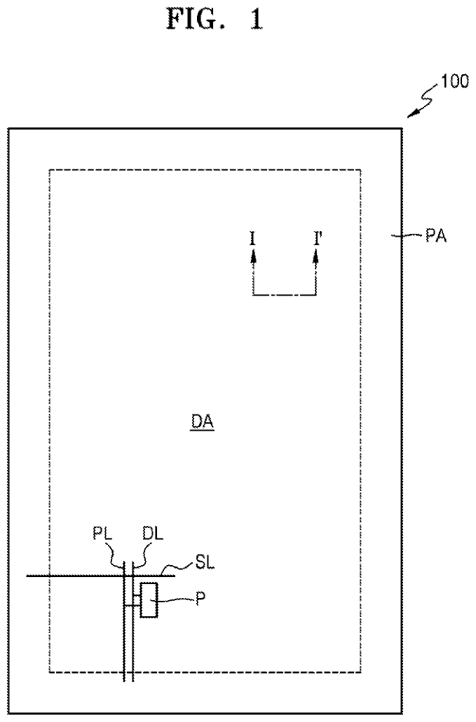

FIG. 1 is a schematic plan view of a display apparatus according to an embodiment.

Referring to FIG. 1, a substrate 100 of a display apparatus 10 may be divided into a display area DA and a peripheral area PA adjacent to (e.g., disposed around) the display area DA. The display apparatus 10 may provide an image (e.g., a certain or selectable image) by using light emitted from pixels P arranged in the display area DA.

Each of the pixels P may include a display element, such as an organic light-emitting diode or an inorganic light-emitting diode, and may emit, for example, red light, green light, blue light, or white light. For example, each pixel P may be electrically connected to a pixel circuit including a thin-film transistor (TFT) and a storage capacitor. The pixel circuit may be electrically connected to a scan line SL, a data line DL intersecting (or crossing) the scan line SL, and a driving voltage line PL. The scan line SL may extend in an x direction, and the data line DL and the driving voltage line PL may extend in a y direction.

Each pixel P may emit light by driving the pixel circuit, and the display area DA may provide an image (e.g., a certain or selectable image) via the light emitted from the pixels P. The pixel P as used herein may be defined as an emission area emitting one of red light, green light, blue light, and white light, as described above.

The pixels P may not be arranged in the peripheral area PA, and an image may not be provided in the peripheral area PA. A printed circuit board including an embedded driving circuit part, a power supply line, and a driving circuit part for driving the pixels P, or a terminal part to which a driver integrated circuit (IC) is electrically connected may be arranged in the peripheral area PA.

The display apparatus 10 according to an embodiment may include an organic light-emitting display, an inorganic electroluminescent (EL) display (e.g., inorganic light-emitting display), a quantum dot display, or the like. Hereinafter, although an organic light-emitting display is described as a display apparatus according to an embodiment, the display apparatus of the disclosure is not limited thereto, and the following features may be applied to various types of display apparatuses as described above.

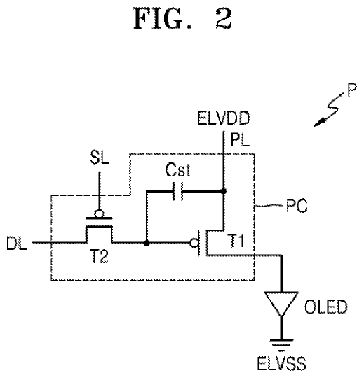

FIG. 2 shows a schematic diagram of an equivalent circuit of a display element provided in a pixel of a display apparatus according to an embodiment, and a pixel circuit electrically connected thereto.

Referring to FIG. 2, an organic light-emitting diode OLED which is a display element may be electrically connected to a pixel circuit PC. The pixel circuit PC may include a first thin-film transistor T1, a second thin-film transistor T2, and a storage capacitor Cst. The organic light-emitting diode OLED may emit, for example, red light, green light, or blue light. For example, the organic light-emitting diode OLED may emit red light, green light, blue light, or white light.

The second thin-film transistor T2, as a switching thin-film transistor, may be electrically connected to the scan line SL and the data line DL. The second thin-film transistor T2 may be configured to transmit, to the first thin-film transistor T1, a data voltage input from the data line DL according to a switching voltage input from the scan line SL. The storage capacitor Cst may be electrically connected to the second thin-film transistor T2 and the driving voltage line PL. The storage capacitor Cst may store a voltage corresponding to a difference between a voltage received from the second thin-film transistor T2 and a first power voltage ELVDD supplied to the driving voltage line PL.

The first thin-film transistor T1, as a driving thin-film transistor, may be electrically connected to the driving voltage line PL and the storage capacitor Cst. The first thin-film transistor T1 may be configured to control a driving current flowing from the driving voltage line PL to the organic light-emitting diode OLED, according to a voltage value stored in the storage capacitor Cst. The organic light-emitting diode OLED may emit light having a luminance (e.g., a certain or selectable luminance) by the driving current. An opposite electrode (e.g., a cathode) of the organic light-emitting diode OLED may receive a second power voltage ELVSS.

Although FIG. 2 illustrates that the pixel circuit PC includes two thin-film transistors and a storage capacitor, in some embodiments, the number of thin-film transistors and/or the number of storage capacitors may vary according to the design of the pixel circuit PC.

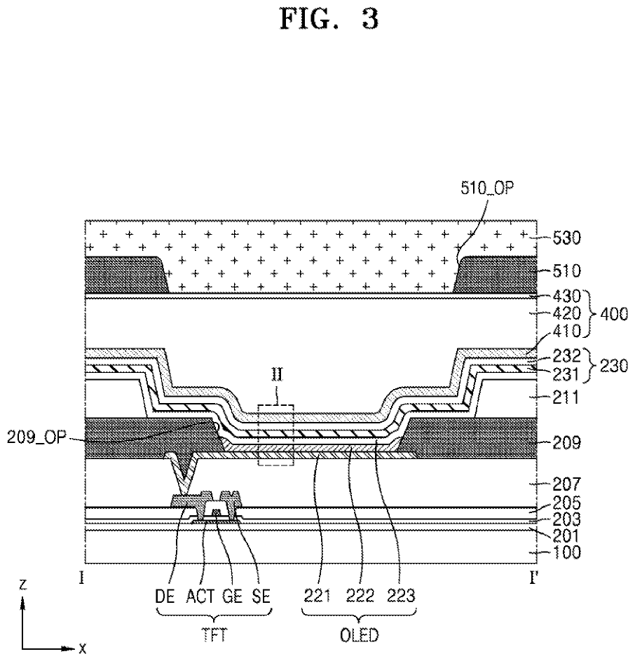

FIG. 3 is a schematic cross-sectional view of a display apparatus according to an embodiment, and is a schematic cross-sectional view of the display apparatus taken along line I-I′ of FIG. 1.

Referring to FIG. 3, the display apparatus according to an embodiment may include the organic light-emitting diode OLED which is a display element including an emission area, a capping layer 230, a thin-film encapsulation layer 400, a light-blocking layer 510 including an opening 510_OP, and a color filter 530 filling the opening 510_OP. The organic light-emitting diode OLED, the capping layer 230, the thin-film encapsulation layer 400, the light-blocking layer 510, and the color filter 530 may be disposed over the substrate 100.

The substrate 100 may be a single layer of glass material. For example, the substrate 100 may include polymer resin. The substrate 100 including polymer resin may have a structure in which a layer including the polymer resin and an inorganic layer are stacked each other. In an embodiment, the substrate 100 may include polymer resin including at least one of polyethersulfone, polyarylate, polyetherimide, polyethylene naphthalate, polyethylene terephthalate, polyphenylene sulfide, polyimide, polycarbonate, cellulose triacetate, and cellulose acetate propionate, and may be flexible. The substrate 100 may include glass containing SiO₂ as a main component. In other embodiments, the substrate 100 may include resin such as reinforced plastic, and may be rigid.

A thin-film transistor TFT may include a semiconductor layer ACT, a gate electrode GE, a source electrode SE, and a drain electrode DE. The semiconductor layer ACT may include at least one of amorphous silicon, polycrystalline silicon, and an organic semiconductor material. A gate insulating layer 203 including at least one inorganic material of silicon oxide, silicon nitride, and silicon oxynitride may be arranged between the semiconductor layer ACT and the gate electrode GE, and the semiconductor layer ACT and the gate electrode GE may be electrically insulated from each other. An interlayer insulating layer 205 including an inorganic material, such as silicon oxide, silicon nitride, and/or silicon oxynitride, may be disposed above the gate electrode GE, and the source electrode SE and the drain electrode DE may be disposed on the interlayer insulating layer 205. An insulating layer including an inorganic material may be formed via chemical vapor deposition (CVD) or atomic layer deposition (ALD).

The gate electrode GE, the source electrode SE, and the drain electrode DE may include various conductive materials. The gate electrode GE may include at least one of molybdenum, aluminum, copper, and titanium, and may have a multi-layer structure as necessary. For example, the gate electrode GE may be a single layer of molybdenum. In other embodiments, the gate electrode GE may have a three-layer structure including a molybdenum layer, an aluminum layer, and a molybdenum layer. Each of the source electrode SE and the drain electrode DE may include at least one of copper, titanium, and aluminum, and may have a multi-layer structure as necessary. For example, each of the source electrode SE and the drain electrode DE may have a three-layer structure including a titanium layer, an aluminum layer, and a titanium layer.

A buffer layer 201 including an inorganic material, such as silicon oxide, silicon nitride, and/or silicon oxynitride may be arranged between the thin-film transistor TFT having the above-described structure and the substrate 100. The buffer layer 201 may increase the smoothness of an upper surface of the substrate 100. For example, the buffer layer 201 may prevent or reduce penetration of impurities from the substrate 100 or the like to the semiconductor layer ACT of the thin-film transistor TFT.

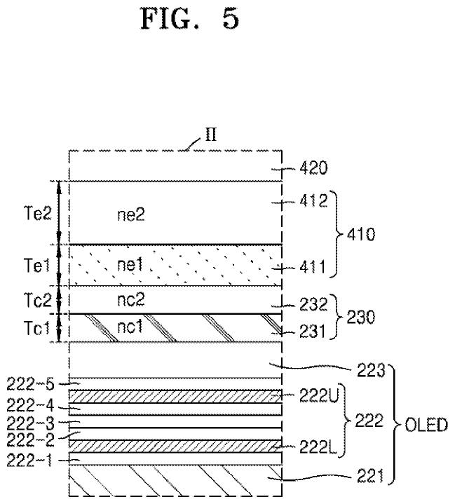

A planarization insulating layer 207 may be disposed on the thin-film transistor TFT. The planarization insulating layer 207 may include, for example, an organic material such as acryl, benzocyclobutene (BCB), or hexamethyldisiloxane (HMDSO). Although FIG. 5 illustrates the planarization insulating layer 207 of a single layer, the planarization insulating layer 207 may be a multi-layer.

A pixel electrode 221 may be disposed on the planarization insulating layer 207. The pixel electrode 221 may be arranged in each pixel. Pixel electrodes 221 (e.g., adjacent pixel electrodes 221) corresponding to respective neighboring pixels (e.g., adjacent pixels) may be arranged apart from each other.

The pixel electrode 221 may be a reflective electrode. In some embodiments, the pixel electrode 221 may include a reflective film including at least one of Ag, Mg, Al, Pt, Pd, Au, Ni, Nd, Jr, Cr, and a compound thereof. For example, the pixel electrode 221 may further include a transparent or semi-transparent electrode layer formed on the reflective film. The transparent or semi-transparent electrode layer may include at least one selected from the group including indium tin oxide (ITO), indium zinc oxide (IZO), zinc oxide (ZnO), indium oxide (In₂O₃), indium gallium oxide (IGO), and aluminum zinc oxide (AZO). In some embodiments, the pixel electrode 221 may have a three-layer structure of an ITO layer, an Ag layer, and an ITO layer.

A pixel-defining layer 209 may be disposed on the pixel electrode 221. The pixel-defining layer 209 may have an opening 209_OP exposing a central portion of each pixel electrode 221. The pixel-defining layer 209 may cover the edge of the pixel electrode 221 and increase a distance between the edge of the pixel electrode 221 and an opposite electrode 223. Thus, the pixel-defining layer 209 may prevent an arc or the like at an edge of the pixel electrode 221. The pixel-defining layer 209 may include at least one organic insulating material of polyimide, polyamide, acrylic resin, BCB, HMDSO, and phenolic resin, and may be formed by a method, such as spin coating. For example, the pixel-defining layer 209 may include an inorganic insulating material. For example, the pixel-defining layer 209 may have a multi-layer structure including an inorganic insulating material and an organic insulating material.

In some embodiments, the pixel-defining layer 209 may include a light-blocking material and may be black. The light-blocking material may include resin (or paste), black dye, metal oxide particles, metal nitride particles, or the like. The resin (or the paste) of the light-blocking material may include at least one of carbon black, carbon nanotubes, and black dye. The metal particles of the light-blocking material may include at least one of Ni, Al, Mo, and alloys thereof. The metal oxide particles of the light-blocking material may include chromium oxide, and the metal nitride particles of the light-blocking material may include chromium nitride. When the pixel-defining layer 209 includes the light-blocking material, reflection of external light by metal structures disposed under the pixel-defining layer 209 may be reduced.

A spacer 211 may be disposed on the pixel-defining layer 209. The spacer 211 may prevent layers arranged between the substrate 100 and the spacer 211 from being damaged by a mask used in a process of forming an emission layer 222. The spacer 211 may include a material identical to that of the pixel-defining layer 209. In some embodiments, the spacer 211 may include a light-blocking material.

The emission layer 222 may be arranged in the opening 209_OP of the pixel-defining layer 209. The emission layer 222 may include an organic material including a fluorescent or phosphorescent material capable of emitting red light, green light, or blue light. The organic material of the emission layer 222 may be a low molecular weight organic material or a polymer organic material. The emission layer 222 may include multiple emission layers 222 overlapping each other (e.g., in a direction or in a plan view). The display apparatus according to an embodiment may have a tandem structure, in which the emission layers 222 are stacked each other, and light efficiency and lifespan of the display apparatus may be improved.

The opposite electrode 223 may be disposed on the emission layer 222. The opposite electrode 223 may be a cathode, which is an electron injection electrode, and a material for forming the opposite electrode 223 may include a metal, an alloy, an electrically conductive compound, or any combination thereof, each having a low work function. The opposite electrode 223 may be a transmissive electrode, a semi-transmissive electrode, or a reflective electrode.

The opposite electrode 223 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or any combination thereof. The opposite electrode 223 may have a single-layered structure including a single layer or may have a multi-layer structure including multiple layers.

A display apparatus may have increased light efficiency by introducing a microcavity. When a reflectance of an opposite electrode is not high, light efficiency may be reduced due to poor resonance. Thus, the light efficiency may be increased by arranging a capping layer on the opposite electrode.

The capping layer 230 may be disposed on the opposite electrode 223. The capping layer 230 may increase external emission efficiency of an organic light-emitting device by the principle of constructive interference.

The capping layer 230 may include multiple capping layers. The capping layer 230 may include a first capping layer 231 and a second capping layer 232. The display apparatus according to an embodiment may include a multi-layer including the plurality of capping layers 230 (e.g., the first capping layer 231 and the second capping layer 232) and the thin-film encapsulation layer 400. The optical characteristics of the capping layer 230 and the thin-film encapsulation layer 400 may be adjusted in consideration of mutual optical characteristics. For example, refractive indices and thicknesses of the first capping layer 231, the second capping layer 232, and a lower inorganic encapsulation layer 410 may have a relationship so that light efficiency and a color shift according to a viewing angle may be adjusted.

Each of the first capping layer 231 and the second capping layer 232 may be an organic capping layer including an organic material, an inorganic capping layer including an inorganic material, or a composite capping layer including an organic material and an inorganic material.

For example, the first capping layer 231 and the second capping layer 232 may include a carbocyclic compound, a heterocyclic compound, an amine group-containing compound, a porphine derivative, a phthalocyanine derivative, a naphthalocyanine derivative, an alkali metal complex, an alkaline earth metal complex, or any combination thereof. The carbocyclic compound, the heterocyclic compound, and the amine group-containing compound may be selectively substituted with a substituent including O, N, S, Se, Si, F, Cl, Br, I, or any combination thereof. The first capping layer 231 and the second capping layer 232 may not include lithium fluoride (LiF).

The thin-film encapsulation layer 400 may be disposed on the capping layer 230. The thin-film encapsulation layer 400 may include at least one inorganic encapsulation layer and at least one organic encapsulation layer. For example, the thin-film encapsulation layer 400 may include the lower inorganic encapsulation layer 410, an organic encapsulation layer 420, and an upper inorganic encapsulation layer 430, as shown in FIG. 3. The lower inorganic encapsulation layer 410 may be in contact with the second capping layer 232. The optical characteristics of the lower inorganic encapsulation layer 410 may be determined in consideration of the optical characteristics of the second capping layer 232 in contact with the lower inorganic encapsulation layer 410 and the first capping layer 231 disposed under the lower inorganic encapsulation layer 410. Accordingly, the display apparatus may have increased light efficiency and an improved color shift according to a viewing angle. For example, in case that the viewing angle is changed, the color shift phenomenon of the display apparatus may not be recognized by a user.

The lower inorganic encapsulation layer 410 and the upper inorganic encapsulation layer 430 may include at least one inorganic insulating material selected from aluminum oxide, titanium oxide, tantalum oxide, hafnium oxide, zinc oxide, silicon oxide, silicon nitride, and silicon oxynitride. Each of the lower inorganic encapsulation layer 410 and the upper inorganic encapsulation layer 430 may have a single-layered or multi-layer structure including the above-described inorganic insulating material. The lower inorganic encapsulation layer 410 may not include lithium fluoride (LiF).

The organic encapsulation layer 420 may relieve internal stress of the lower inorganic encapsulation layer 410 and/or the upper inorganic encapsulation layer 430. The organic encapsulation layer 420 may include a polymer-based material. The polymer-based material may include polyethylene terephthalate, polyethylene naphthalate, polycarbonate, polyimide, polyethylene sulfonate, polyoxymethylene, polyarylate, hexamethyldisiloxane, acrylic resin (for example, polymethyl methacrylate and polyacrylic acid), or any combination thereof.

The organic encapsulation layer 420 may be formed by applying a monomer having flowability and then curing the monomer layer using heat or light such as ultraviolet rays. As another example, the organic encapsulation layer 420 may be formed by applying the above-described polymer-based material.

Even in case that cracks occur in the thin-film encapsulation layer 400 via the above-described multi-layer structure, the thin-film encapsulation layer 400 may prevent such cracks from being connected between the lower inorganic encapsulation layer 410 and the organic encapsulation layer 420 or between the organic encapsulation layer 420 and the upper inorganic encapsulation layer 430. Accordingly, the formation of a path through which moisture or oxygen from the outside penetrates into the display area DA may be prevented or reduced.

The light-blocking layer 510 and the color filter 530 may be disposed above the thin-film encapsulation layer 400.

The light-blocking layer 510 may be disposed on the thin-film encapsulation layer 400. The light-blocking layer 510 may include light-blocking insulating material. Accordingly, the light-blocking layer 510 may be a colored and opaque light-blocking insulating layer, and may appear, for example, black. For example, the light-blocking layer 510 may include a polyimide (PI)-based binder and a pigment in which red, green, and blue are mixed. In another example, the light-blocking layer 510 may include a binder resin and a mixture of a lactam black pigment and a blue pigment. In another example, the light-blocking layer 510 may include carbon black.

The light-blocking layer 510 may include the opening 510_OP overlapping the emission area of the organic light-emitting diode OLED (e.g., in a direction or in a plan view). The emission area may be defined by the opening 209_OP of the pixel-defining layer 209. The opening 510_OP of the light-blocking layer 510 may be filled with the color filter 530.

The color filter 530 may be disposed above the light-blocking layer 510 and fill the opening 510_OP of the light-blocking layer 510. Accordingly, the light-blocking layer 510 may be in contact with the color filter 530. The color filter 530 may pass only light in a wavelength band (e.g., a specific or selectable wavelength band) to which a wavelength of the light from the display element disposed under the color filter 530 belongs.

The color filter 530 may reduce reflection of external light in the display apparatus. For example, when external light reaches a color filter disposed above a display element emitting red light, only light having a wavelength band corresponding to red light may pass through the color filter, and light of other wavelengths may be absorbed by the color filter. Therefore, of external light incident on a display apparatus, only light having a wavelength belonging to a wavelength band corresponding to red light may pass through a color filter, and a part of the external light passing through the color filter may be reflected from an opposite electrode or pixel electrode under the color filter and emitted to the outside again. As a result, only a part of the external light may be reflected to the outside, and the color filter may reduce reflection of external light.

The color filter 530 may cover the light-blocking layer 510. For example, the color filter 530 may cover an upper surface of the light-blocking layer 510 in a direction (e.g., in a +z direction) away from the substrate 100. The light-blocking layer 510 may prevent external light from traveling to the display element and the like. In other embodiments, the external light may be partially reflected by the upper surface of the light-blocking layer 510. Therefore, the upper surface of the light-blocking layer 510 may be covered with a material having a reflectance lower than a reflectance of the light-blocking layer 510, an amount of reflected external light may be further reduced. Since a reflectance of the light-blocking layer 510 is approximately 4%, the color filter 530 having a reflectance of approximately 3% may cover the light-blocking layer 510.

In case that a polarizing film is used to reduce reflection of external light, transmittance of light emitted from the organic light-emitting diode OLED may be significantly reduced by the polarizing film. Since the display apparatus according to an embodiment includes the light-blocking layer 510 and the color filter 530, light transmittance may be increased, and at the same time, reflection of external light may be reduced.

A cover window (not illustrated) may be disposed above the color filter 530. The cover window may be attached onto the color filter 530 by a clear adhesive member, such as an optically clear adhesive film.

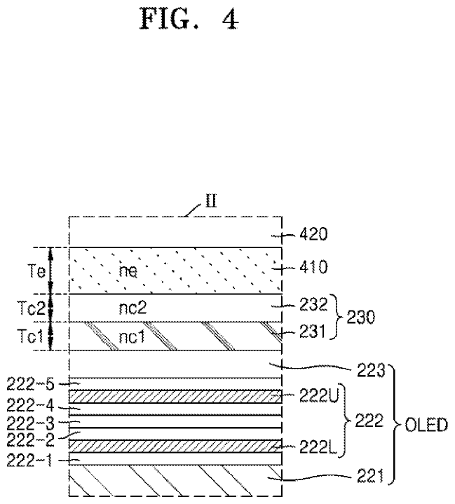

FIG. 4 is an enlarged schematic cross-sectional view of portion II of FIG. 3, according to an embodiment.

Referring to FIG. 4, the display apparatus according to an embodiment may include the organic light-emitting diode OLED provided as a display element, the first capping layer 231, the second capping layer 232, the lower inorganic encapsulation layer 410, and the organic encapsulation layer 420. The organic light-emitting diode OLED may include the pixel electrode 221, the emission layer 222, and the opposite electrode 223.

As shown in FIG. 4, the organic light-emitting diode OLED may include multiple emission layers 222 overlapping each other in a thickness direction. For example, the organic light-emitting diode OLED may have a tandem structure. Accordingly, light efficiency may be increased, and lifespan of the display apparatus may be extended.

For example, the organic light-emitting diode OLED may include a lower emission layer 222L and an upper emission layer 222U. The upper emission layer 222U may be disposed on the lower emission layer 222L and overlap the lower emission layer 222L in a plan view. For example, the emission layers 222 may include the lower emission layer 222L and the upper emission layer 222U. The lower and upper emission layers 222L and 222U overlapping each other in a plan view may emit light of a same wavelength or may emit light of different wavelengths.

A first common layer 222-1 may be arranged between the pixel electrode 221 and the lower emission layer 222L. The first common layer 222-1 may have a single-layered or multi-layer structure. For example, when the first common layer 222-1 includes a polymer material, the first common layer 222-1, as a hole transport layer (HLT) having a single-layered structure, may include at least one of poly-(3,4-ethylenedioxythiophene (PEDOT), polyaniline (PANI), N, N′-diphenyl-N,N′-bis (3-methylphenyl)-1,1′-bi-phenyl-4,4′-diamine (TPD), and N,N′-di(naphthalen-1-yl)-N,N′-diphenyl-benzidine (NPB). When the first common layer 222-1 includes a low molecular weight material, the first common layer 222-1 may include a hole injection layer (HIL) and a hole transport layer (HTL).

A second common layer 222-5 may be disposed above the upper emission layer 222U. The second common layer 222-5 may not always be provided (or may be omitted). For example, when the first common layer 222-1 and the emission layer 222 include a polymer material, the second common layer 222-5 may be formed on the upper emission layer 222U. The second common layer 222-5 may have a single-layered or multi-layer structure. The second common layer 222-5 may include an electron transport layer (ETL) and/or an electron injection layer (EIL). The opposite electrode 223 may be disposed on the second common layer 222-5.

A charge generation layer 222-3 may be further arranged between the lower emission layer 222L and the upper emission layer 222U. The charge generation layer 222-3 may supply charges (e.g., electric charges) to a first stack including the lower emission layer 222L and a second stack including the upper emission layer 222U.

A third common layer 222-2 may be further arranged between the charge generation layer 222-3 and the lower emission layer 222L. A fourth common layer 222-4 may be further arranged between the charge generation layer 222-3 and the upper emission layer 222U. The third common layer 222-2 may include an electron transport layer, and the fourth common layer 222-4 may include a hole transport layer.

The first capping layer 231, the second capping layer 232, and the lower inorganic encapsulation layer 410 may be sequentially disposed over the organic light-emitting diode OLED. The lower inorganic encapsulation layer 410 may be in contact with the second capping layer 232. A thickness Te of the lower inorganic encapsulation layer 410 may be greater than a thickness Tc1 of the first capping layer 231 and may be greater than a thickness Tc2 of the second capping layer 232. The thickness Te of the lower inorganic encapsulation layer 410 may be at least about 500 Å and not more than about 10,000 Å (or may be in a range of about 500 Å to about 10,000 Å). Each of the thickness Tc1 of the first capping layer 231 and the thickness Tc2 of the second capping layer 232 may be at least about 100 Å and not more than about 2,000 Å (or may be in a range of about 100 Å to about 2,000 Å).

Refractive indices of the first capping layer 231, the second capping layer 232, and the lower inorganic encapsulation layer 410 may have a relationship. The lower inorganic encapsulation layer 410 may have a refractive index greater than that of the second capping layer 232 in contact with the lower inorganic encapsulation layer 410. For example, a refractive index ne of the lower inorganic encapsulation layer 410 may be greater than a refractive index nc2 of the second capping layer 232. The first capping layer 231 may have a refractive index greater than that of the second capping layer 232 in contact with the first capping layer 231. For example, a refractive index nc1 of the first capping layer 231 may be greater than the refractive index nc2 of the second capping layer 232.

The refractive index ne of the lower inorganic encapsulation layer 410 may be at least about 1.59 and not more than about 1.95 (or may be in a range of about 1.59 to about 1.95). For example, the refractive index ne of the lower inorganic encapsulation layer 410 may be about 1.62 or about 1.77. The refractive index nc2 of the second capping layer 232 may be at least about 1.2 and not more than about 1.8 (or may be in a range of about 1.2 to about 1.8). The refractive index nc1 of the first capping layer 231 may be at least about 1.8 and not more than about 2.4 (or may be in a range of about 1.8 to about 2.4).

Since light emitted from the organic light-emitting diode OLED arranged in each pixel passes through the capping layer 230 and the thin-film encapsulation layer 400 and travels to the outside, a color shift phenomenon may occur when viewed in a direction oblique to a direction (e.g., z direction) perpendicular to the substrate 100 due to an interference phenomenon. When a display apparatus includes a tandem structure having a stack of emission layers to increase light efficiency, a color shift phenomenon according to a viewing angle may increase.

In the display apparatus according to an embodiment, since the capping layer 230 and the thin-film encapsulation layer 400, which are disposed on the tandem structure, have the above-described optical characteristics, a color shift phenomenon may be improved or a color shift pattern may be adjusted.

FIG. 5 is an enlarged schematic cross-sectional view of portion II of FIG. 3, according to an embodiment different from that of FIG. 4. The same reference numerals in FIGS. 4 and 5 denote the same members, and thus, redundant descriptions thereof are omitted.

Referring to FIG. 5, the display apparatus according to an embodiment may include the organic light-emitting diode OLED provided as a display element, the first capping layer 231, the second capping layer 232, the lower inorganic encapsulation layer 410, and the organic encapsulation layer 420. The lower inorganic encapsulation layer 410 may include a first inorganic encapsulation layer 411 in contact with the second capping layer 232 and a second inorganic encapsulation layer 412 disposed above the first inorganic encapsulation layer 411.

As shown in FIG. 5, the organic light-emitting diode OLED may include emission layers 222 (e.g., the lower emission layer 222L and the upper emission layer 222) overlapping each other in a thickness direction. For example, the organic light-emitting diode OLED may have a tandem structure. Accordingly, light efficiency may be increased, and lifespan of the display apparatus may be extended.

The first capping layer 231, the second capping layer 232, the first inorganic encapsulation layer 411, and the second inorganic encapsulation layer 412 may be sequentially disposed over the organic light-emitting diode OLED. The first inorganic encapsulation layer 411 may be in contact with the second capping layer 232. The second inorganic encapsulation layer 412 may cover the first inorganic encapsulation layer 411 to serve as a buffer.

A thickness Te2 of the second inorganic encapsulation layer 412 may be greater than a thickness Te1 of the first inorganic encapsulation layer 411. The thickness Te2 of the second inorganic encapsulation layer 412 may be greater than the thickness Tc1 of the first capping layer 231 and may be greater than the thickness Tc2 of the second capping layer 232. The thickness Te1 of the first inorganic encapsulation layer 411 may be greater than the thickness Tc1 of the first capping layer 231 and may be greater than the thickness Tc2 of the second capping layer 232.

The thickness Te2 of the second inorganic encapsulation layer 412 may be at least about 1,000 Å and not more than about 15,000 Å (or may be in a range of about 1,000 Å to about 15,000 Å). The thickness Te1 of the first inorganic encapsulation layer 411 may be at least about 500 Å and not more than about 10,000 Å (or may be in a range of about 500 Å to about 10,000 Å). Each of the thickness Tc1 of the first capping layer 231 and the thickness Tc2 of the second capping layer 232 may be at least about 100 Å and not more than about 2,000 Å (or may be in a range of about 100 Å to about 2,000 Å).

Refractive indices of the first capping layer 231, the second capping layer 232, the first inorganic encapsulation layer 411, and the second inorganic encapsulation layer 412 may have a relationship (e.g., a certain or selectable relationship). The first inorganic encapsulation layer 411 may have a refractive index greater than that of the second capping layer 232 disposed under the first inorganic encapsulation layer 411. For example, a refractive index ne1 of the first inorganic encapsulation layer 411 may be greater than the refractive index nc2 of the second capping layer 232. The first inorganic encapsulation layer 411 may have a refractive index greater than that of the second inorganic encapsulation layer 412 disposed above the first inorganic encapsulation layer 411. For example, the refractive index ne1 of the first inorganic encapsulation layer 411 may be greater than a refractive index ne2 of the second inorganic encapsulation layer 412. The first capping layer 231 may have a refractive index greater than that of the second capping layer 232. The refractive index nc1 of the first capping layer 231 may be greater than the refractive index nc2 of the second capping layer 232.

The refractive index ne1 of the first inorganic encapsulation layer 411 may be at least about 1.46 and not more than about 1.95 (or be in a range of about 1.46 to about 1.95). For example, the refractive index ne1 of the first inorganic encapsulation layer 411 may be about 1.62 or about 1.77. The refractive index ne2 of the second inorganic encapsulation layer 412 may be about 1.62 or about 1.57. The refractive index nc2 of the second capping layer 232 may be at least about 1.2 and not more than about 1.8 (or may be in a range of about 1.2 to about 1.8). The refractive index nc1 of the first capping layer 231 may be at least about 1.8 and not more than about 2.4 (or may be in a range of about 1.8 to about 2.4).

In case that a display apparatus includes a tandem structure having a stack of multiple emission layers to increase light efficiency, a color shift phenomenon according to a viewing angle may increase. However, as in the embodiment, since the refractive indices of the first capping layer 231, the second capping layer 232, and the first inorganic encapsulation layer 411 have the above-described relationship, a color shift phenomenon may be improved (or may not be recognized by a user) or a color shift pattern may be adjusted. The second inorganic encapsulation layer 412 serving as a buffer may be disposed on the first inorganic encapsulation layer 411, and distribution of emitted color may be improved.

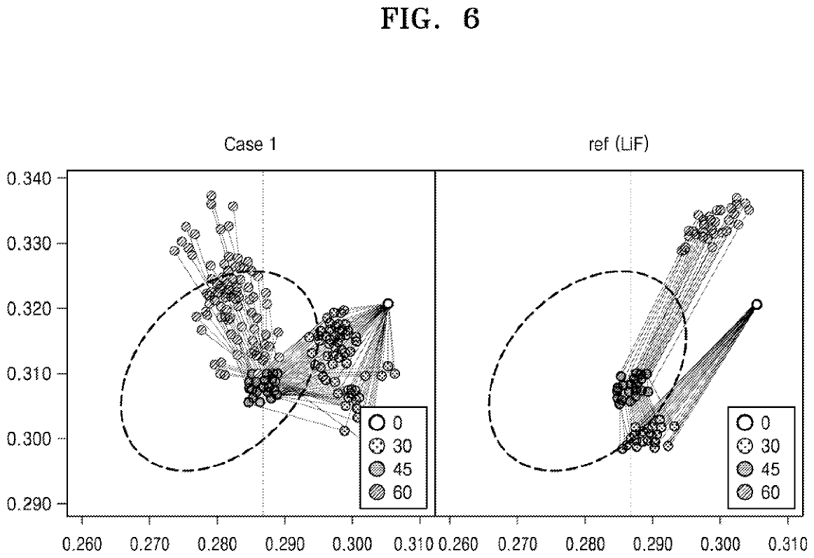

FIG. 6 is a graph schematically showing a white angular dependency (WAD) trajectory of a display apparatus via ‘CIE 1931’, according to an embodiment. A WAD phenomenon refers to a phenomenon in which colors change according to a viewing angle of a display apparatus, for example, a color shift phenomenon according to a viewing angle. FIG. 6 is a graph showing a WAD trajectory as a viewing angle was changed based on an axis perpendicular to the substrate 100. FIG. 6 is a result of measurement at viewing angles of 0°, 30°, 45°, and 60°.

Comparative Example (ref) is a WAD trajectory that appears in a general display apparatus having a tandem structure. In the case of Comparative Example (ref), an inorganic layer including lithium fluoride (LiF) was in contact with and was disposed on the second capping layer 232.

Example 1 (case 1) is a WAD trajectory that appeared when refractive indices of the lower inorganic encapsulation layer 410 and the second capping layer 232 in contact with the lower inorganic encapsulation layer 410 in FIG. 4 were adjusted to have the above-described relationship. In Example 1 (case 1), the second capping layer 232 and the lower inorganic encapsulation layer 410 in contact with the second capping layer 232 did not include lithium fluoride (LiF).

Referring to FIG. 6, in the case of Comparative Example (ref), a blue-based color was exhibited at 45°, and a yellow-based color was exhibited at 60°. For example, in the case of Comparative Example (ref), when the viewing angle was increased from 45° to 60°, the color had a large change from the blue-based color to the yellow-based color, and thus, the change in color according to the viewing angle could be more readily recognized by users of the display apparatus.

In contrast, in Example 1 (case 1), a blue-based color was exhibited at both about 45° and about 60°. In case that the viewing angle was increased from about 45° to about 60°, a color shift occurred. However, the trajectory was shorter than that of Comparative Example (ref), and the color shift could be made in a direction that was difficult for users to recognize.

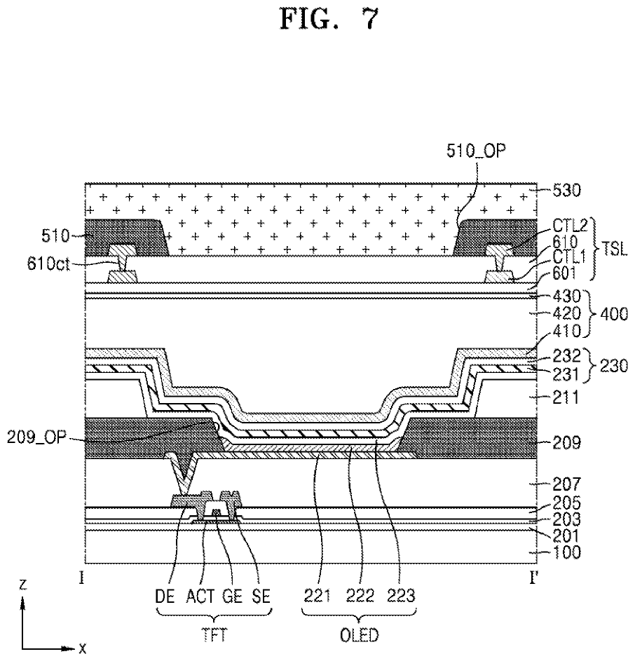

FIG. 7 is a schematic cross-sectional view of a display apparatus according to an embodiment. The same reference numerals in FIGS. 3 and 7 denote the same members, and thus, redundant descriptions thereof are omitted.

Referring to FIG. 7, the display apparatus according to an embodiment may include the organic light-emitting diode OLED as a display element including an emission area, the first capping layer 231, the second capping layer 232, the lower inorganic encapsulation layer 410, the organic encapsulation layer 420, the upper inorganic encapsulation layer 430, the light-blocking layer 510 including the opening 510_OP, and the color filter 530 filling the opening 510_OP. The organic light-emitting diode OLED, the first capping layer 231, the second capping layer 232, the lower inorganic encapsulation layer 410, the organic encapsulation layer 420, the upper inorganic encapsulation layer 430, the light-blocking layer 510, and the color filter may be disposed over the substrate 100. Referring to FIGS. 4 and 5, the organic light-emitting diode OLED included in the display apparatus according to an embodiment may have a tandem structure. The lower inorganic encapsulation layer 410 may have a refractive index greater than that of the second capping layer 232 in contact with the lower inorganic encapsulation layer 410. In another example, the lower inorganic encapsulation layer 410 may include the first inorganic encapsulation layer 411 in contact with the second capping layer 232 and the second inorganic encapsulation layer 412 disposed above the first inorganic encapsulation layer 411, and the first inorganic encapsulation layer 411 may have a refractive index greater than that of the second capping layer 232. The second inorganic encapsulation layer 412 may have a refractive index lower than that of the first inorganic encapsulation layer 411. As such, the optical characteristics of the capping layer 230 and the lower inorganic encapsulation layer 410 may be adjusted, and a color shift phenomenon may be improved or a color shift pattern may be adjusted.

In the embodiment, a touch sensing layer TSL may be arranged between the thin-film encapsulation layer 400 and the light-blocking layer 510. The touch sensing layer TSL may be a layer that senses a user's touch input and may detect a user's touch input by using at least one of various touch types, such as a resistive type and a capacitive type.

The touch sensing layer TSL may be disposed on the thin-film encapsulation layer 400. The touch sensing layer TSL may include a first sub-conductive layer CTL1, a second sub-conductive layer CTL2, and a touch insulating layer 610. The touch sensing layer TSL may further include a touch buffer layer 601.

The touch buffer layer 601 may be formed (e.g., directly formed) above the thin-film encapsulation layer 400. The touch buffer layer 601 may prevent damage to the thin-film encapsulation layer 400 and may block interference signals that may occur when the touch sensing layer TSL is driven. The touch buffer layer 601 may include an inorganic insulating material, such as silicon oxide (SiOₓ), silicon nitride (SiNₓ), and silicon oxynitride (SiOₓ N_{y}), or an organic material, and may be provided as a single layer or a multilayer.

The first sub-conductive layer CTL1, the touch insulating layer 610, and the second sub-conductive layer CTL2 may be sequentially stacked one another above the touch buffer layer 601. The first sub-conductive layer CTL1 and the second sub-conductive layer CTL2 may be disposed below and above the touch insulating layer 610, respectively. In some embodiments, the second sub-conductive layer CTL2 may act as a sensor part that detects a contact (e.g., a touch of a user), and the first sub-conductive layer CTL1 may serve as a connecting portion that electrically connects the patterned second sub-conductive layer CTL2 in a direction. In another embodiment, the first sub-conductive layer CTL1 may act as a sensor part that detects a contact (e.g., a touch of a user), and the second sub-conductive layer CTL2 may serve as a connecting portion that electrically connects the patterned first sub-conductive layer CTL1 in a direction.

In some embodiments, both the first sub-conductive layer CTL1 and the second sub-conductive layer CTL2 may act as sensor parts. The first sub-conductive layer CTL1 and the second sub-conductive layer CTL2 may be electrically connected through a contact hole 610ct formed in the touch insulating layer 610. As such, as both the first sub-conductive layer CTL1 and the second sub-conductive layer CTL2 are used as the sensor parts, resistance of a touch electrode may decrease, and thus, a response speed of the touch sensing layer TSL may increase.

In some embodiments, the first sub-conductive layer CTL1 and the second sub-conductive layer CTL2 may have a mesh structure, and light emitted from the organic light-emitting diode OLED may pass through the first sub-conductive layer CTL1 and the second sub-conductive layer CTL2. Accordingly, the first sub-conductive layer CTL1 and the second sub-conductive layer CTL2 may be arranged so as not to overlap the emission area of the organic light-emitting diode OLED in a plan view. For example, the emission area of the organic light-emitting diode OLED may be disposed in openings of the mesh structure formed by the first sub-conductive layer CTL1 and the sub-conductive layer CTL2.

The first sub-conductive layer CTL1 and the second sub-conductive layer CTL2 may include a metal layer or a transparent conductive layer, and the metal layer may include at least one of molybdenum (Mo), silver (Ag), titanium (Ti), copper (Cu), aluminum (Al), and an alloy thereof. The transparent conductive layer of the first sub-conductive layer CTL1 and the second sub-conductive layer CTL2 may include a transparent conductive oxide, such as indium tin oxide (ITO), indium zinc oxide (IZO), zinc oxide (ZnO), and indium tin zinc oxide (ITZO). The transparent conductive layer may include at least one of a conductive polymer such as PEDOT, a metal nanowire, a carbon nanotube, and graphene. In an embodiment, each of the first sub-conductive layer CTL1 and the second sub-conductive layer CTL2 may have a three-layered structure of a titanium layer, an aluminum layer, and a titanium layer.

The touch insulating layer 610 may include an inorganic material or an organic material. The inorganic material of the touch insulating layer 610 may be at least one of silicon nitride, aluminum nitride, zirconium nitride, titanium nitride, hafnium nitride, tantalum nitride, silicon oxide, aluminum oxide, titanium oxide, tin oxide, cerium oxide, and silicon oxynitride. The organic material may be at least one of acrylic resin, methacrylic resin, polyisoprene, vinyl-based resin, epoxy-based resin, urethane-based resin, cellulose-based resin, and perylene-based resin.

The light-blocking layer 510 and the color filter 530 may be disposed above the touch sensing layer TSL, and may reduce reflection of external light by the first sub-conductive layer CTL1 and the second sub-conductive layer CTL2 included in the touch sensing layer TSL.

As described above, the display apparatus according to an embodiment may include emission layers overlapping each other in a plan view, a capping layer, and an inorganic encapsulation layer, and refractive indices of the capping layer and the inorganic encapsulation layer may have a relationship (e.g., a certain or selectable relationship) to increase light efficiency and to allow a color shift to occur in a direction that is not readily visible to a user.

The above description is an example of technical features of the disclosure, and those skilled in the art to which the disclosure pertains will be able to make various modifications and variations. Thus, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display apparatus comprising:
a display element comprising:
a first emission layer disposed on a substrate; and
a second emission layer disposed on the first emission layer;
a first capping layer disposed on the display element;
a second capping layer disposed on the first capping layer;
a thin-film encapsulation layer comprising a lower inorganic encapsulation layer in contact with the second capping layer; and
a light-blocking layer disposed on the thin-film encapsulation layer and comprising an opening corresponding to an emission area of the display element,
wherein the lower inorganic encapsulation layer has a refractive index greater than a refractive index of the second capping layer.

2. The display apparatus of claim 1, wherein the refractive index of the lower inorganic encapsulation layer is in a range of about 1.59 to about 1.95.

3. The display apparatus of claim 1, wherein
the lower inorganic encapsulation layer comprises:
a first inorganic encapsulation layer in contact with the second capping layer; and
a second inorganic encapsulation layer disposed on the first inorganic encapsulation layer, and
the first inorganic encapsulation layer has a refractive index greater than a refractive index of the second inorganic encapsulation layer.

4. The display apparatus of claim 3, wherein the refractive index of the first inorganic encapsulation layer is in a range of about 1.46 to about 1.95.

5. The display apparatus of claim 3, wherein a thickness of the first inorganic encapsulation layer is less than a thickness of the second inorganic encapsulation layer.

6. The display apparatus of claim 1, wherein the first capping layer has a refractive index greater than the refractive index of the second capping layer.

7. The display apparatus of claim 6, wherein
the refractive index of the first capping layer is in a range of about 1.8 to about 2.4, and
the refractive index of the second capping layer is in a range of about 1.2 to about 1.8.

8. The display apparatus of claim 1, wherein the display element further comprises:
a pixel electrode disposed under the first emission layer; and
an opposite electrode disposed on the second emission layer.

9. The display apparatus of claim 1, wherein the thin-film encapsulation layer further comprises:
an upper inorganic encapsulation layer disposed on the lower inorganic encapsulation layer; and
an organic encapsulation layer arranged between the lower inorganic encapsulation layer and the upper inorganic encapsulation layer.

10. The display apparatus of claim 1, further comprising:
a color filter filling the opening of the light-blocking layer.

11. A display apparatus comprising:
a pixel electrode disposed on a substrate;
a plurality of emission layers disposed on the pixel electrode and overlapping each other in a plan view;
an opposite electrode disposed on the plurality of emission layers;
a first capping layer disposed on the opposite electrode;
a second capping layer disposed on the first capping layer;
a first inorganic encapsulation layer in contact with the second capping layer; and
a light-blocking layer disposed on the first inorganic encapsulation layer and comprising at least one opening corresponding to the plurality of emission layers,
wherein each of a refractive index of the first capping layer and a refractive index of the first inorganic encapsulation layer is greater than a refractive index of the second capping layer.

12. The display apparatus of claim 11, wherein the refractive index of the first inorganic encapsulation layer is in a range of about 1.59 to about 1.95.

13. The display apparatus of claim 11, further comprising:
a second inorganic encapsulation layer disposed on the first inorganic encapsulation layer,
wherein the refractive index of the first inorganic encapsulation layer is greater than a refractive index of the second inorganic encapsulation layer.

14. The display apparatus of claim 13, wherein
the refractive index of the first inorganic encapsulation layer is in a range of about 1.46 to about 1.95, and
the refractive index of the second inorganic encapsulation layer is in a range of about 1.41 to about 1.78.

15. The display apparatus of claim 13, wherein a thickness of the first inorganic encapsulation layer is less than a thickness of the second inorganic encapsulation layer.

16. The display apparatus of claim 13, wherein a thickness of the first inorganic encapsulation layer is greater than a thickness of each of the first capping layer and the second capping layer.

17. The display apparatus of claim 11, wherein the refractive index of the first capping layer is greater than the refractive index of the second capping layer.

18. The display apparatus of claim 11, further comprising:
an organic encapsulation layer disposed on the first inorganic encapsulation layer; and
an upper inorganic encapsulation layer disposed on the organic encapsulation layer.

19. The display apparatus of claim 18, further comprising:
a touch sensing layer arranged between the upper inorganic encapsulation layer and the light-blocking layer.

20. The display apparatus of claim 11, further comprising:
a color filter filling the at least one opening of the light-blocking layer.
